(19) United States
(12) Patent Application Publication
(10) Pub. No.: US 2022/0061190 A1
(43) Pub. Date: Feb. 24, 2022

(54) WASTE HEAT WRAPAROUND PREVENTION METHOD AND PARTITION

(71) Applicant: NIPPON TELEGRAPH AND TELEPHONE CORPORATION, Tokyo (JP)

(72) Inventors: Tomomi NAGAO, Musashino-shi, Tokyo (JP); Atsushi SAKURAI, Musashino-shi, Tokyo (JP)

(21) Appl. No.: 17/312,544

(22) PCT Filed: Dec. 9, 2019
(86) PCT No.: PCT/JP2019/048110

§ 371 Date: Jun. 10, 2021

(30) Foreign Application Priority Data
Dec. 12, 2018 (JP) 2018-232929

(51) Int. Cl. H05K 7/20

(52) U.S. Cl. CPC H05K 7/20745

(57) ABSTRACT

In a machine room in which an air conditioner and ICT devices are installed, a partition is installed on a side, facing the air conditioner, of an aisle between two ICT devices that are installed so that air intake surfaces of the two ICT devices face each other.

### TECHNICAL FIELD

The present invention relates to power saving in a machine room, and particularly relates to power saving of an air conditioner.

### BACKGROUND ART

In a data center or a communication machine room, it is necessary to take measures against heat emitted by communication devices in order to prevent failure of the communication devices to be operated, and the communication devices are cooled using an air conditioner in many cases.

On the other hand, from the viewpoint of power saving, it is preferable to efficiently use air conditioning in order to reduce the amount of power used by an air conditioner. One airflow design method for improving the efficiency of air conditioning is “Aisle capping (trade name)” that clearly separates cold air exhaled by an air conditioner from hot air discharged by a communication device (Non Patent Literature 1).

The “Aisle capping (trade name)” disclosed in Non Patent Literature 1 is a method of creating a space surrounding a cold aisle that is an aisle in which air intake surfaces of communication devices face each other, and preventing exhaust heat wraparound.

### CITATION LIST

### Non Patent Literature

Non Patent Literature 1: http://www.ntt-f.co.jp/service/data_center/aco_aislecapping/, searched on Dec. 10, 2018

### SUMMARY OF THE INVENTION

### Technical Problem

According to the method disclosed in Non Patent Literature 1, a superior effect for preventing exhaust heat wraparound can be expected, but it is necessary to install facilities on a ceiling portion and facilities on both sides of a space for forming a cold aisle, and thus installation and construction costs are often high.

In addition, because the space is closed at all times, it is necessary to open and close the space on every entering and leaving during work such as maintenance of the communication devices, which leads to a complicated operation.

The present invention is contrived in view of the above points, and an object thereof is to provide a technique of preventing exhaust heat wraparound which can be achieved at low cost and enables a simple operation in a machine room in which an air conditioner and a plurality of ICT devices are installed.

### Means for Solving the Problem

According to the disclosed technique, there is provided a method of preventing exhaust heat wraparound in a machine room in which an air conditioner and a plurality of ICT devices are installed, wherein a partition is installed on a side, facing the air conditioner, of an aisle between two ICT devices among the plurality of ICT devices that are installed so that air intake surfaces of the two ICT devices face each other.

### Effects of the Invention

According to the disclosed technique, it is possible to provide a technique of preventing exhaust heat wraparound which can be achieved at low cost and enables a simple operation.

### BRIEF DESCRIPTION OF DRAWINGS

FIG. 1 is a plan view illustrating an airflow image of exhaust heat of communication devices.

FIG. 2 is a side view illustrating an airflow image of the communication devices.

FIG. 3 is a plan view illustrating an airflow image of exhaust heat of the communication devices after the introduction of a partition.

FIG. 4 is a diagram illustrating installation example 1 of the partition.

FIG. 5 is a front view of the partition.

FIG. 6 is a diagram illustrating installation example 2 of the partition.

FIG. 7 is a plan view of an upper partition.

### DESCRIPTION OF EMBODIMENTS

Hereinafter, an embodiment of the present invention will be described with reference to the accompanying drawings. An embodiment to be described below is an example, and an embodiment to which the present invention is applied is not limited to the following embodiment.

For example, although in the following embodiment, the present invention is assumed to be applied to cooling of communication devices installed in a communication machine room, the present invention is not limited to a communication machine room and communication devices, and can be applied to various types of machine rooms and various types of information and communications technology (ICT) devices. Examples of such a machine room include a communication machine room, a computer room, a server room, and the like. Examples of the ICT device include a communication device such as a switchboard, a switch, or a router, a server, a computer, a patch panel, a patch panel control robot, and the like. In addition, in the present embodiment, a communication machine room of a double floor system is assumed, but the present invention can also be applied to a case where a floor that is not a double floor system is used.

In addition, in the present embodiment, the communication device is assumed to be mounted in a rack, but such a configuration is an example. For example, a configuration in which the communication device itself has a shape like a rack may be used, a configuration in which the communication device itself is stacked without using a rack or the like may be used, or other configurations may be used. In addition, a rack having the communication device mounted therein may be referred to as a “communication device”. Such a “communication device” is also an example of the ICT device. In addition, a row of racks having the communication device mounted therein may be referred to as a “communication device”. Such a “communication device” is also an example of the ICT device.

Problem of Exhaust Heat of Communication Device

As described above, a double floor system is adopted in the communication machine room according to the present embodiment, and cold air provided by the air conditioner exits to an upper portion through a double floor, and is sucked from an air intake surface of the communication device. The cold air changes to warm air due to the communication device, and the warm air is discharged from the communication device. The warm air (exhaust heat) discharged from the communication device returns to the air conditioner through a space on the double floor.

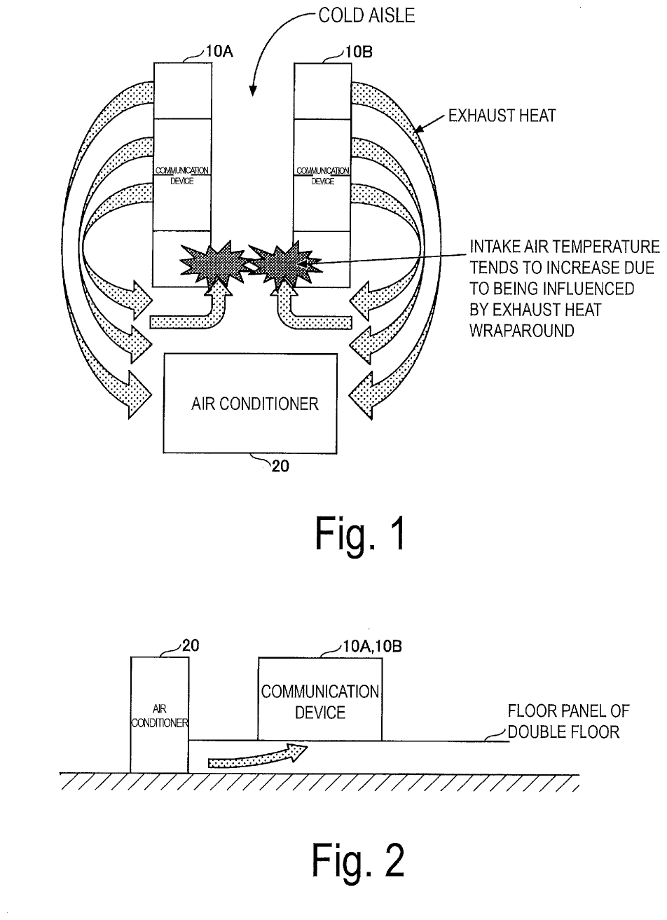

FIG. 1 is a diagram illustrating an airflow image of exhaust heat of the communication devices. FIG. 1 is a plan view when an air conditioner 20 and communication devices 10A and 10B in the communication machine room are viewed from above. Each of the communication device 10A and the communication device 10B is composed of four racks. Meanwhile, the number of racks is an example.

The communication device 10A and the communication device 10B are installed such that air intake surfaces for sucking cold air (the right side of the communication device 10A and the left side of the communication device 10B) are facing each other. An aisle between the air intake surface of the communication device 10A and the air intake surface of the communication device 10B is referred to as a cold aisle.

As illustrated in FIG. 1, the air conditioner 20 and the communication devices 10A and 10B are disposed so that the front of the air conditioner 20 (the surface on the side facing the communication devices 10A and 10B) and the air intake surfaces of the communication devices 10A and 10B are perpendicular to each other. However, the word “perpendicular” need not be strictly perpendicular. The word “perpendicular” may be replaced with “substantially perpendicular”, “approximately perpendicular”, or the like.

FIG. 2 is a side view when the air conditioner 20 and the communication devices 10A and 10B are viewed from the side. Cold air sent out from the air conditioner 20 rises, is sent out from the floor surface of the cold aisle, and is sucked from the air intake surfaces of the communication devices 10A and 10B, and then exhaust heat is discharged from the back surfaces of the communication devices 10A and 10B.

As illustrated in FIG. 1, because the exhaust heat of the communication devices 10A and 10B returns toward the air conditioner 20, some of the exhaust heat may wrap around to portions of the air intake surfaces of the communication devices 10A and 10B on the sides close to the air conditioner 20. For this reason, the communication devices 10A and 10B may be inhibited from sucking the cold air in those portions.

### Installation Example 1 of Partition

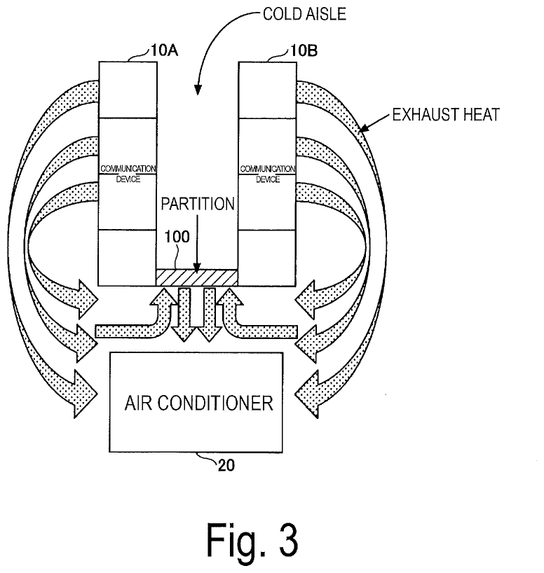

Consequently, in the present embodiment, as illustrated in FIG. 3, a partition 100 is installed at an entrance of the cold aisle on the side facing the air conditioner 20. That is, as illustrated in FIG. 3, the partition 100 is installed between a corner portion on the cold aisle side which is the end surface of the communication device 10A on the air conditioner 20 side and a corner portion on the cold aisle side which is the end surface of the communication device 10B on the air conditioner 20 side. As can be seen by comparing FIG. 1 with FIG. 3, the exhaust heat from the air conditioner 20 side can be prevented from wrapping around to the air intake surfaces by installing the partition 100.

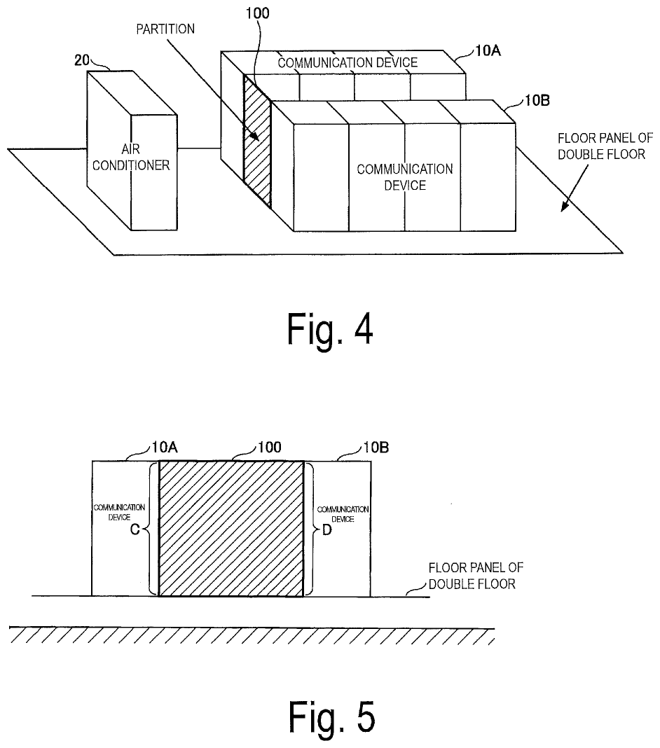

FIG. 4 is a perspective view when the air conditioner 20 and the communication devices 10A and 10B are viewed from obliquely above in a case where the partition 100 is installed.

As illustrated in FIG. 4, the partition 100 is installed at the entrance of an aisle (cold aisle) on the side facing the air conditioner 20.

In the example illustrated in FIG. 4, the partition 100 has a rectangular shape, and is configured such that its lower end is in contact with the floor surface and its height is the same as the height of the communication devices 10A and 10B. However, this is an example. Insofar as the exhaust heat can be prevented from wrapping around to the air intake surfaces, the lower end of the partition 100 may not be in contact with the floor surface. In addition, the height of the partition 100 may be larger or smaller than the height of the communication devices 10A and 10B within a range of a certain threshold. In addition, the thickness of the partition 100 is not particularly limited, and may be thick enough to maintain its shape.

The partition 100 is configured to have a structure in which entering and leaving are possible in order to make it possible for a person to enter and leave an aisle between the communication devices 10A and 10B and to perform work on the communication devices 10A and 10B. Specifically, a structure such as a noren type, a roller screen type, or an accordion type can be used. In addition, door types such as double swing doors or a single swing door may be used. Meanwhile, the partition 100 being configured to have a structure in which entering and leaving are possible is an example, and the partition 100 may be configured to have a structure in which entering and leaving are impossible (a fixed structure).

In addition, as for the material of the partition 100, any material may be used for preventing exhaust heat wraparound, but it is preferable to use a material for ensuring flame resistance, flame retardancy, and heat resistance.

In addition, any method can be used as a method of installing the partition at a position illustrated in FIG. 4. For example, in FIG. 5 (a front view when the partition 100 is viewed from the air conditioner 20 side), a portion indicated by C (a right-end corner portion of the end surface of the communication device 10A on the air conditioner side), a portion indicated by D (a left-end corner portion of the end surface of the communication device 10B on the air conditioner side), or both C and D may be provided with a member for installing the partition 100, and the partition 100 can be installed on these members.

Meanwhile, in the example of FIG. 5, it is illustrated that the partition 100 is a member having no window, but this is an example. For example, a portion having no influence on the prevention of exhaust heat wraparound may be provided with a window. In addition, FIG. 5 illustrates an example in which there are no gaps between the partition 100 and the sides of the communication devices 10A and 10B, but there may be gaps in a range having no influence on the prevention of exhaust heat wraparound.

### Installation Example 2 of Partition

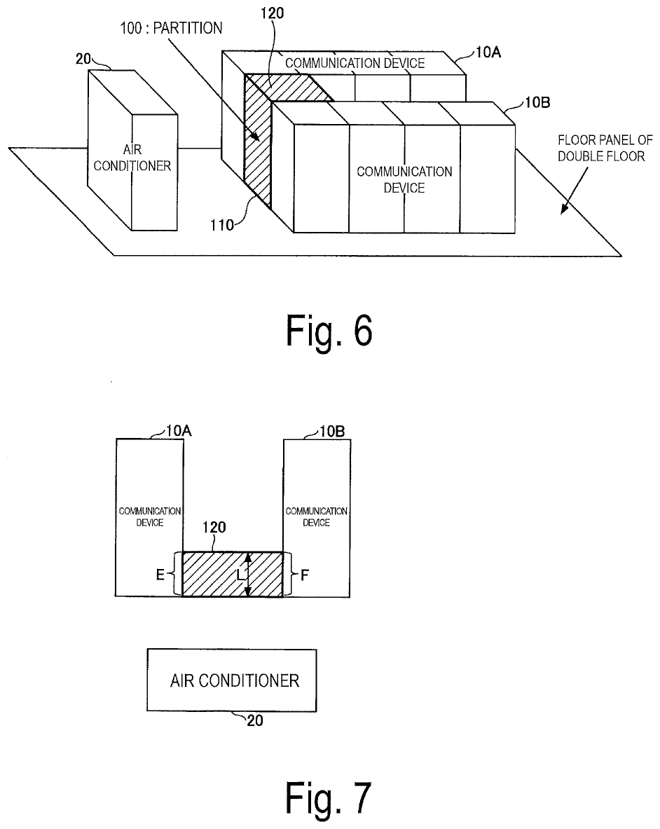

FIG. 6 is a diagram illustrating another example of the partition 100. The partition 100 illustrated in FIG. 6 includes a front partition 110 installed on the front surface of the air conditioner 20 equivalent to the partition 100 described in FIG. 4 or the like as installation example 1 of the partition and an upper partition 120 installed on the upper portion of air intake surfaces of the communication devices 10A and 10B (and the surfaces of the communication devices 10A and 10B on the air conditioner 20 side). The upper partition 120 is additionally provided, so that it is possible to prevent the exhaust heat wraparound from the upper portion, and to obtain a better effect of preventing the exhaust heat wraparound.

The front partition 110 is the same as the partition 100 described in example 1 of the partition. The upper partition 120 is configured as a movable type, for example, by adopting a roller screen type or the like in order to have no influence on workability. However, the movable type is an example, and a non-movable type structure such as a plate or a sheet may be used. The thickness of the upper partition 120 is not particularly limited, and may be thick enough to maintain its shape.

Any method can be used as a method of installing the upper partition 120 at a position illustrated in FIG. 6. For example, in FIG. 7 (a plan view when viewed from above), a portion indicated by E (a right-end corner portion of the top surface of the communication device 10A), a portion indicated by F (a left-end corner portion of the top surface of the communication device 10B), or both E and F may be provided with a member for installing the upper partition 120, and the upper partition 120 may be installed on these members. Meanwhile, the front partition 110 and the upper partition 120 may be connected to each other, or may be separated from each other with a certain degree of gap (a range having no influence on the prevention of exhaust heat wraparound) interposed therebetween. In addition, the front partition 110 and the upper partition 120 may be an integrated member.

FIG. 7 illustrates an example in which there are no gaps between the upper partition 120 and the sides of the communication devices 10A and 10B, but there may be gaps in a range having no influence on the prevention of exhaust heat wraparound.

The length of the depth of the upper partition 120 (L in FIG. 7) can be determined, for example, as a length capable of effectively preventing the exhaust heat wraparound by observing the wraparound of the exhaust heat from the upper portion. For example, as illustrated in FIG. 7, the length of the depth of the upper partition 120 may be set to a length of approximately one rack. Meanwhile, the length of the depth of the upper partition 120 being a length of approximately one rack is merely an example.

### Effects of Embodiment

As described above, in the present embodiment, the partition is installed only on a portion that tends to be influenced by the wraparound of exhaust heat rather than on the whole cold aisle. This makes it possible to achieve a reduction in cost, and to achieve the prevention of exhaust heat wraparound which enables a simple operation. In addition, because a closed space is not formed, safety is also improved. As a result, this contributes to improving the efficiency of air conditioning in a communication machine room.

That is, it is possible to prevent exhaust heat wraparound to the air intake surface of the communication device with a simple structure, and to improve the efficiency of air conditioning without lowering the workability of a machine room.

### Conclusion of Embodiment

At least the following are disclosed in the present specification.

### Paragraph 1

A method of preventing exhaust heat wraparound in a machine room in which an air conditioner and a plurality of ICT devices are installed, wherein a partition is installed on a side, facing the air conditioner, of an aisle between two ICT devices among the plurality of ICT devices that are installed so that air intake surfaces of the two ICT devices face each other.

### Paragraph 2

The method of preventing exhaust heat wraparound according to paragraph 1, wherein the aisle is a cold aisle, and the partition is installed at an entrance of the cold aisle on a side facing the air conditioner.

### Paragraph 3

The method of preventing exhaust heat wraparound according to paragraph 1 or 2, wherein an upper partition is further installed at a part of an upper portion of the aisle on a side of the air conditioner.

### Paragraph 4

A partition for preventing exhaust heat wraparound in a machine room in which an air conditioner and a plurality of ICT devices are installed, wherein the partition is installed on a side, facing the air conditioner, of an aisle between two ICT devices among the plurality of ICT devices that are installed so that air intake surfaces of the two ICT devices face each other.

### Paragraph 5

The partition according to paragraph 4, wherein the aisle is a cold aisle, and the partition is installed at an entrance of the cold aisle on a side facing the air conditioner.

### Paragraph 6

The partition according to paragraph 4 or 5, further including an upper partition which is installed at a part of an upper portion of the aisle on a side of the air conditioner.

Hereinbefore, although the present embodiment has been described, the present invention is not limited to such a specific embodiment, and can be modified and changed variously without departing from the scope of the present invention described in the aspects.

### REFERENCE SIGNS LIST

10A, 10B Communication device
20 Air conditioner
100 Partition
110 Front partition
120 Upper partition

1. A method of preventing exhaust heat wraparound in a machine room in which an air conditioner and a plurality of Information and Communications Technology (ICT) devices are installed, wherein a partition is installed on a side, facing the air conditioner, of an aisle between two ICT devices among the plurality of ICT devices that are installed so that air intake surfaces of the two ICT devices face each other.

2. The method of preventing exhaust heat wraparound according to claim 1, wherein the aisle is a cold aisle, and the partition is installed at an entrance of the cold aisle on a side facing the air conditioner.

3. The method of preventing exhaust heat wraparound according to claim 1, wherein an upper partition is further installed at a part of an upper portion of the aisle on a side of the air conditioner.

4. A partition for preventing exhaust heat wraparound in a machine room in which an air conditioner and a plurality of ICT devices are installed, wherein the partition is installed on a side, facing the air conditioner, of an aisle between two ICT devices among the plurality of ICT devices that are installed so that air intake surfaces of the two ICT devices face each other.

5. The partition according to claim 4, wherein the aisle is a cold aisle, and the partition is installed at an entrance of the cold aisle on a side facing the air conditioner.

6. The partition according to claim 4, further comprising an upper partition which is installed at a part of an upper portion of the aisle on a side of the air conditioner.
